(19) United States
(12) Patent Application Publication
(10) Pub. No.: US 2016/0027617 A1
(43) Pub. Date: Jan. 28, 2016

(54) PLASMA GENERATING UNIT AND SUBSTRATE TREATING APPARATUS HAVING THE SAME

(71) Applicant: Semes Co., Ltd, Cheonan-si (KR)

(72) Inventors: Duk Hyun SON, Cheonan-si (KR); Jung Hwan LEE, Ansan-si (KR)

(21) Appl. No.: 14/796,620

(22) Filed: Jul. 10, 2015

(30) Foreign Application Priority Data
Jul. 25, 2014 (KR) 10-2014-0095064

(51) Int. Cl. H01J 37/32; H01J 37/244

(52) U.S. Cl. CPC H01J 37/32183; H01J 37/3244; H01J 37/3211; H01J 37/244

(57) ABSTRACT

Disclosed are an apparatus for treating a substrate and a plasma generating device. The apparatus for treating a substrate includes a process chamber, a support unit supporting the substrate in the process chamber, a gas supply unit supplying a process gas in the process chamber, and a plasma generating unit generating a plasma from the process gas supplied in the process chamber, and the plasma generating unit includes a high frequency power supply, an antenna unit connected to the high frequency power via a supply line, and an impedance matcher connected between the high frequency power supply and the antenna unit via the supply line and matching impedance, and the impedance matcher includes a first sensor connected to an input terminal and measuring input impedance and a second sensor connected to an output terminal and measuring output impedance.

### CROSS-REFERENCE TO RELATED APPLICATIONS

A claim for priority under 35 U.S.C. §119 is made to Korean Patent Application No. 10-2014-0095064 filed Jul. 25, 2015, in the Korean Intellectual Property Office, the entire contents of which are hereby incorporated by reference.

### BACKGROUND

The inventive concept described herein relate to a plasma generating unit and an apparatus for treating a substrate having the same.

A semiconductor manufacture process may include a process for treating a substrate using plasma. For example, an etching process in the semiconductor manufacture process may remove a thin film on a substrate using plasma.

A plasma generating unit may be installed in a process chamber to use plasma in a process for treating a substrate. The plasma generating unit may be roughly classified into a capacitively coupled plasma (hereinafter referred as to “CCP”) type and an inductively coupled plasma (hereinafter referred as to “ICP”) type based on a plasma generating method.

A source of the CCP type may be arranged in a chamber such that two electrodes are opposite to each other. The CCP type of the plasma generating unit may apply a radio frequency (hereinafter referred as to “RF”) signal to one or both of the two electrodes to generate an electric field in the chamber, thereby making it possible to generate plasma.

When two or more coils are installed in a chamber and two or more coils receive a power from one RF power supply, an impedance matcher may be installed between the RF power and the coils. Here, to match impedance, a sensor may measure input impedance on an input terminal of the impedance matcher to control matching impedance. However, the method of controlling the matching impedance does not take a parasitic capacitor and an inductor in the impedance matcher into account. Therefore, the matching time may increase and a process failure may occur.

### SUMMARY

One aspect of embodiments of the inventive concept is directed to provide a plasma generating unit capable of matching impedance within a short time and a substrate treating apparatus having the same.

The technical objectives of the inventive concept are not limited to the above disclosure; other objectives may become apparent to those of ordinary skill in the art based on the following descriptions.

The inventive concept may provide an apparatus for treating a substrate.

In accordance with one aspect of the inventive concept, an apparatus for treating a substrate includes a process chamber, a support unit supporting the substrate in the process chamber, a gas supply unit supplying a process gas in the process chamber, and a plasma generating unit generating a plasma from the process gas supplied in the process chamber, and the plasma generating unit includes a high frequency power supply, an antenna unit connected to the high frequency power via a supply line, and an impedance matcher connected between the high frequency power supply and the antenna unit via the supply line and configured to match impedance, and the impedance matcher includes a first sensor connected to an input terminal and configured to measure input impedance and a second sensor connected to an output terminal and configured to measure output impedance.

The impedance matcher may further include an inductor connected between the first sensor and the second sensor via the supply line, a first variable capacitor connected between the inductor and the second sensor, and a second variable capacitor connected to the first variable capacitor in parallel.

The plasma generating unit may further include a controller configured to transmit a control signal to the impedance matcher, and the controller may control values of the first valuable capacitor and the second valuable capacitor after measuring the output impedance using the second sensor.

The second variable capacitor may be connected between a division point of the supply line and a ground.

The division point may be located between the first sensor and the inductor.

The antenna unit may include a first antenna connected to the high frequency power supply through a line and a second antenna connected to the first antenna in parallel.

Each of the first antenna and the second antenna may have a ring shape, and a radius of the first antenna may be smaller than that of the second antenna.

An embodiment of the inventive concept may provide a plasma generating device and an apparatus for treating a substrate, which are capable of matching impedance within a short time.

### BRIEF DESCRIPTION OF THE FIGURES

The above and other objects and features will become apparent from the following description with reference to the following figures, wherein like reference numerals refer to like parts throughout the various figures unless otherwise specified, and wherein

FIG. 1. is a cross-sectional view schematically illustrating an apparatus for treating a substrate, according to an embodiment of the inventive concept;

FIG. 2 is a circuit diagram schematically illustrating a plasma generating unit according to an embodiment of the inventive concept;

FIG. 3 is a circuit diagram illustrating a plasma generating unit shown in FIG. 2;

FIG. 4 is a flow chart illustrating a general matching control method according to a related art; and

FIG. 5 is a flow chart illustrating a matching control method according to an embodiment of the inventive concept;

### DETAILED DESCRIPTION

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

An apparatus for treating a substrate etching the substrate using a plasma may be described in an embodiment of the inventive concept. However, the inventive concept is not limited hereto but may be applied to various kinds of devices heating a substrate located on an upper side of the apparatus for treating a substrate.

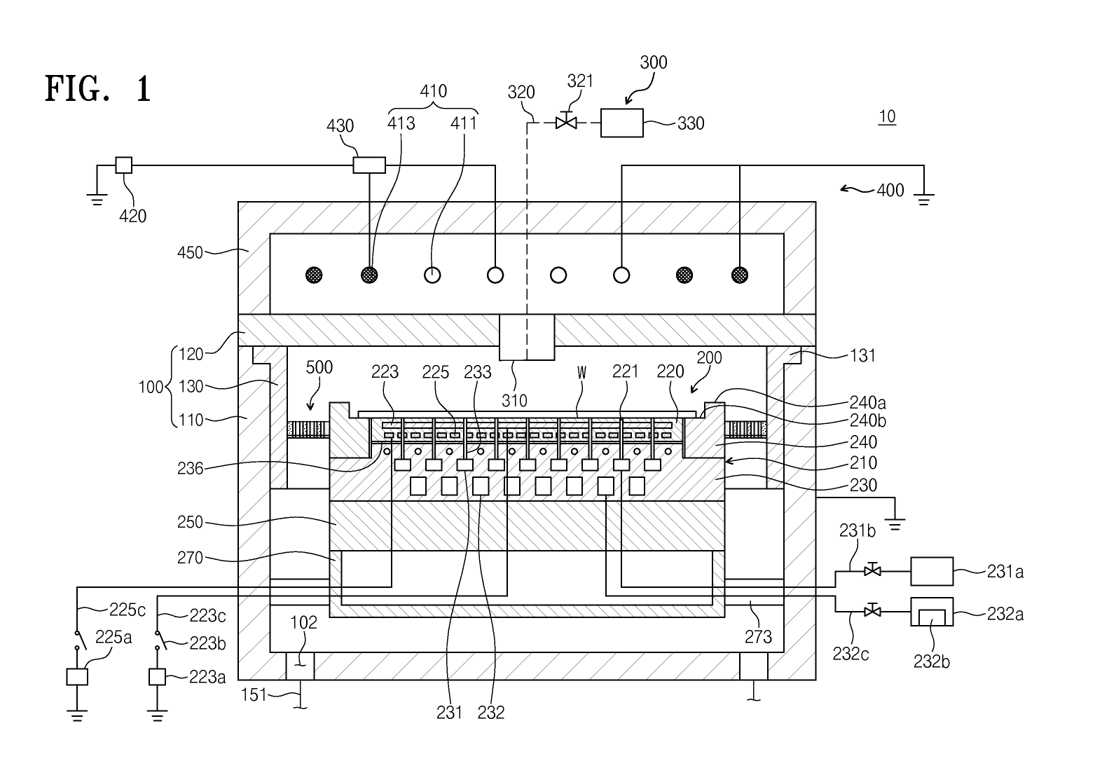

FIG. 1 is a cross-sectional view schematically illustrating an apparatus for treating a substrate according to an embodiment of the inventive concept.

Referring to FIG. 1, a substrate treating apparatus 10 may treat a substrate W using plasma. For example, the substrate treating apparatus 10 may perform an etching process with respect to the substrate W. The substrate treating apparatus 10 may include a process chamber 100, a substrate support unit 200, a gas supply unit 300, a plasma generating unit 400, and a baffle unit 500.

The process chamber 100 may provide a space for performing a process for treating a substrate. The process chamber 100 may include a housing 110, a sealing cover 120, and a liner 130.

A top end portion of the housing 110 may be opened. The process for treating a substrate may be performed in an internal space of the housing 110. The housing 110 may be made of metal material. For example, the housing 110 may be made of aluminum material. The housing 110 may be grounded. An exhaust hole 102 may be formed on a bottom surface of the housing 110. The exhaust hole 102 may be connected to an exhaust line 151. A reaction by-product generated in a process step and a gas which exists in an internal space of the housing 110 may be discharged through the exhaust line 151. The internal space of the housing 110 may be decompressed to a predetermined compression by an exhaust process.

The sealing cover 120 may cover an opened top end portion of the housing 110. The sealing cover 120 may have a plate shape and seal the internal space of the housing 110. The sealing cover 120 may include a dielectric substance window.

The liner 130 may be installed in the housing 110. The liner 130 may be formed in a space where a top end portion and a bottom end portion are opened. The liner 130 may have a cylinder shape. The liner 130 may have a radius corresponding to a diameter of a sidewall of the housing 110. The liner 130 may be installed along an inner sidewall of the housing 110. A support ring 131 may be formed on a top end portion of the liner 130. The support ring 131 may be manufactured with a plate having a ring shape and protrude outward from the liner 130 along a circumference of the liner 130. The support ring 131 may be located on a top end portion of the housing 110. The support ring 131 may support the liner 131. The liner 130 may be made of the same material as the housing 110. For example, the liner 130 may be made of aluminum material. The liner 130 may protect an inner sidewall of the housing 110. When a process gas is excited, an arc discharge may occur in the process chamber 100. The arc discharge may damage peripheral devices. The liner 130 may protect the inner sidewall of the housing 110, thereby making it possible to prevent the inner sidewall of the housing 110 from the arc discharge. Furthermore, the liner 130 may prevent impurities generated during a process for treating a substrate from being deposited on the inner sidewall of the housing 110. The liner 130 may be cheaper than the housing 110. Moreover, to exchange the liner 130 may be easier than to exchange the housing 110. Therefore, when the liner 130 is damaged due to the arc discharge, a worker may replace the damaged liner 130 with a new liner 130.

A substrate support unit 200 may be located in the housing 110. The substrate support unit 200 may support the substrate W. The substrate support unit 200 may include an electrostatic chuck 210 for holding a substrate W using an electrostatic force. On the other hand, the substrate support unit 200 may support a substrate W in various methods such as a mechanical clamping. A substrate support unit 200 including the electrostatic chuck 210 may be described as follows.

The substrate support unit 200 may include an electrostatic chuck 210, an insulation plate 250, and a bottom cover 270. The substrate support unit 200 may be installed to be apart from the bottom surface of the housing 110 in the process chamber 100.

The electrostatic chuck 210 may include a dielectric plate 220, a bottom electrode 223, a heater 225, a support plate 230, and a focus ring 240.

The dielectric plate 220 may be located on the electrostatic chuck 210. The dielectric plate 220 may be a dielectric substance having a circular shape. A substrate W may be stacked on the dielectric plate 220. Because a radius of the dielectric plate 220 is smaller than that of the substrate W, a boundary area of the substrate W may be located outside the dielectric plate 220. A first supply fluid path 221 may be formed in the dielectric plate 220. The first supply fluid path 221 may be formed to penetrate the dielectric plate 220. The first supply fluid path 221 may include a plurality of fluid paths which are spaced apart from each other. The first supply fluid path 221 may be used as a path through which heat transmission media is supplied to a bottom surface of the substrate W.

The bottom electrode 223 and the heater 225 may be buried in the dielectric plate 220. The bottom electrode 223 may be located on the heater 225. The bottom electrode 223 may be electrically connected to a first bottom power supply 223a. The first bottom power supply 223a may include a direct current (hereinafter referred to as “DC”) power supply. A switch 223b may be installed between the bottom electrode 223 and the first bottom power supply 223a. The bottom electrode 223 may be electrically connected to a first bottom power supply 223a in response to activation of the switch 223b. When the switch 223b is turned on, the DC power supply may be applied to the bottom electrode 223. An electrostatic force generated by a current applied to the bottom electrode 223 may operate between the bottom electrode 223 and the substrate W. The substrate W may be held on the dielectric plate 220 by the electrostatic force.

The heater 225 may be electrically connected to a second bottom power supply 225a. The heater 225 may resist a current from the second bottom power supply 225a, thereby making it possible to generate heat. The heat may be transmitted to the substrate W through the dielectric plate 220. The substrate W may maintain a predetermined temperature by the heat generated from the heater 225. The heater 225 may include a helical coil.

A support plate 230 may be located under the dielectric plate 220. A bottom surface of the dielectric plate 220 and a top surface of the support plate 230 may be adhered by an adhesive 236. The support plate 230 may be made of aluminum material. A center area of the top surface of the support plate 230 may be higher than a boundary area. The center area of the support plate 230 may correspond to the bottom surface of the dielectric plate 220 and may be adhered to the bottom surface of the dielectric plate 220. A first circulation fluid path 231, a second circulation fluid path 232, and a second supply fluid path 233 may be formed in the support plate 230.

The first circulation fluid path 231 may be used as a path through which heat transmission media is circulated. The first circulation fluid path 231 may be formed in the support plate 230 in a helical shape. Moreover, the first circulation fluid path 231 may include ring-shaped first fluid paths having different radii. The first fluid paths may be arranged such that centers of the first fluid paths have the same height. The first fluid paths may be connected with each other. The first fluid paths may have the same height.

The second circulation fluid path 232 may be used as a path through which heat transmission media is circulated. The second circulation fluid path 232 may be formed in the support plate 230 in a helical shape. Moreover, the second circulation fluid path 232 may include ring-shaped second fluid paths having different radii. The second fluid paths may be arranged such that the second fluid paths have the same center. The second fluid paths may be connected with each other. Each of the second fluid paths may have a cross-sectional area larger than each of the first fluid paths. The second fluid paths may be formed at the same height. Each of the second fluid paths may be located under the first circulation fluid path 231.

The second supply fluid path 233 may extend upward from the first circulation fluid path 231 and be arranged on the support plate 230. The number of fluid paths of the second supply fluid path 233 may correspond to that of fluid paths of the first supply fluid path 221. The second supply fluid path 233 may connect the first circulation fluid path 231 and the first supply fluid path 221.

The first circulation fluid path 231 may be connected to a heat transmission media storage unit 231a via a supply line 231b. The heat transmission media storage unit 231a may store heat transmission media. The heat transmission media may include an inert gas. In an embodiment, the heat transmission media may include a helium gas. The helium gas may be supplied to the first circulation fluid path 231 via the supply line 231b. Moreover, the helium gas may be supplied to the bottom surface of the substrate W through the second supply fluid path 233 and the first supply fluid path 221. The helium gas may be a media through which heat transmitted from plasma to the substrate W is transmitted to the electrostatic chuck 210.

The second circulation fluid path 232 may be connected to a cooling fluid storage unit 232a via a cooling fluid supply line 232c. The cooling fluid storage unit 232a may store cooling fluid. The cooling fluid storage unit 232a may include a cooler 232b. The cooler 232b may lower a temperature of the cooling fluid. On the other hand, the cooler 232b may be installed on the cooling fluid supply line 232c. The cooling fluid supplied to the second circulation fluid path 232 via the cooling fluid supply line 232c may circulate along the second circulation fluid path 232, thereby making it possible to cool the support plate 230. As cooled, the support plate 230 may cool both the dielectric plate 220 and the substrate W to allow a substrate W to remain at a predetermined temperature.

A focus ring 240 may be arranged in a boundary area of the electrostatic chuck 210. The focus ring 240 may have a ring shape and be arranged along a circumstance of the dielectric plate 220. A top surface of the focus ring 240 may be installed such that an outer top surface 240a is higher than an inner top surface 240b. The inner top surface 240b of the focus ring 240 may be located at the same height as a top surface of the dielectric plate 220. The inner top surface 240b of the focus ring 240 may support a boundary area of the substrate W located outside the dielectric plate 220. The outer top surface 240a may surround the boundary area of the substrate W. Plasma in the process chamber 100 may be focused on an area, opposite to the substrate W, via the focus ring 240.

An insulation plate 250 may be located under the support plate 230. The insulation plate 250 may have a cross-sectional area corresponding to that of the support plate 230. The insulation plate 250 may be located between the support plate 230 and the bottom cover 270. The insulation plate 250 may have insulation material and electrically insulate the support plate 230 and the bottom cover 270.

The bottom cover 270 may be located in a bottom end portion of the substrate support unit 200. The bottom cover 270 may be installed to be spaced apart from the bottom surface of the housing 110. The bottom cover 270 may have a space of which a top end portion is opened. The insulation plate 250 may cover the bottom cover 270. Accordingly, an outer radius of a cross-sectional area of the bottom cover 270 may be equal to an outer radius of the insulation plate 250. A left pin module (not shown) for moving the substrate W to be returned from an outside return element to the electrostatic chuck 210 may be located in the bottom cover 270.

The bottom cover 270 may have a connection element 273. The connection element 273 may connect an outer sidewall of the bottom cover 270 and an inner sidewall of the housing 110. The connection element 273 may include a plurality of connection elements which are placed between the outer sidewall of the bottom cover 270 and the inner sidewall of the housing 110 and are spaced apart from each other. The connection element 273 may support the substrate support unit 200 in the process chamber 100. Further, the connection element 273 may be connected to the inner sidewall of the housing 110, thereby making it possible for the bottom cover 270 to electrically be grounded. A first power line 223c connected to a first bottom power 223a, a second power line 225c connected to a second bottom power 225a, a heat transmission media supply line 231b connected to the heat transmission media storage unit 231a, and a cooling fluid supply line 232c connected to the cooling fluid storage unit 232a may extend into the bottom cover 270 via an inner space of the connection element 273.

The gas supply unit 300 may provide a process gas into the process chamber 100. The gas supply unit 300 may include a gas supply nozzle 310, a gas supply line 320, and a gas storage unit 330. The gas supply nozzle 310 may be installed in a center area of the sealing cover 120. An injection nozzle may be formed on a bottom surface of the gas supply nozzle 310. The injection nozzle may be located on a bottom surface of the sealing cover 120 and provide a process gas into a process space in the process chamber 100. The gas supply line 320 may connect the gas supply nozzle 310 and the gas storage unit 330. The gas supply line 320 may provide a process gas stored in the gas storage unit 330 to the gas supply nozzle 310. A valve 321 may be installed on the gas supply line 320. The valve 321 may turn on or off the gas supply line 320 and adjust the amount of process gas supplied via the gas supply line 320.

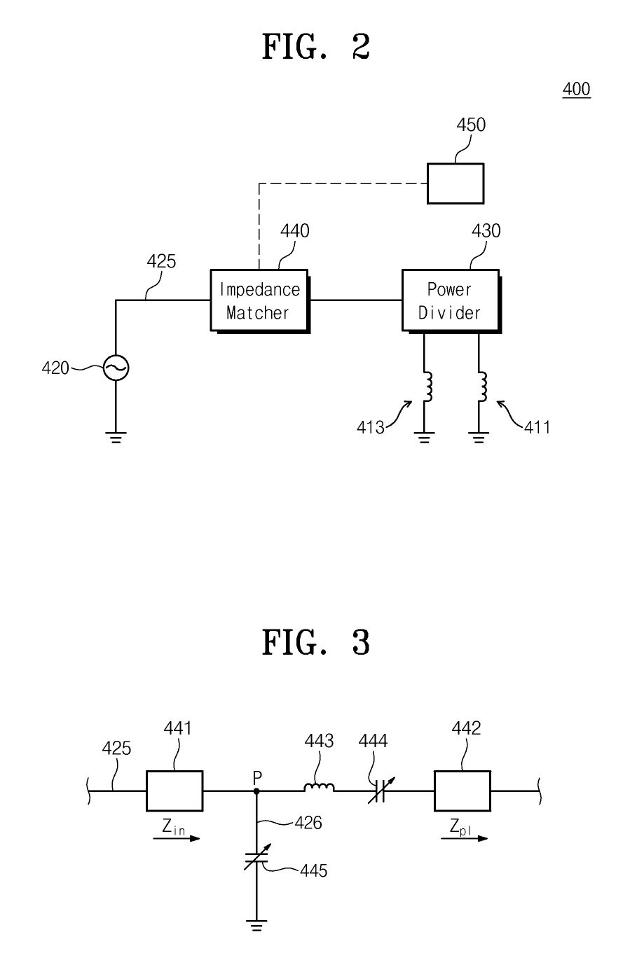

FIG. 2 is a circuit diagram schematically illustrating a plasma generating unit 400 according to an embodiment of the inventive concept. A plasma generating unit 400 may make a process gas into a plasma state. In an embodiment, the plasma generating unit 400 may be implemented in an ICP-type.

The plasma generating unit 400 may include an antenna unit 410, a high frequency power supply 420, a power divider 430, an impedance matcher 440, and a controller 450. The high frequency power supply 420 may provide a high frequency signal. In an embodiment, the high frequency power supply 420 may be a radio frequency (hereinafter referred to as “RF”) power supply 420. The RF power supply 420 may generate a RF signal. According to an embodiment of the inventive concept, the RF power supply 420 may generate a sinusoidal wave having a predetermined frequency. However, a waveform of a signal generated by the RF power supply 420 may not be limited thereto and have various waveforms such as a saw tooth wave and a triangular wave.

The antenna unit 410 may be connected to the RF power supply 420 via a supply line 425. The antenna unit 410 may receive a RF signal from the RF power supply 420 to induce an electromagnetic field, thereby making it possible to generate plasma. The antenna unit 410 may have a plurality of antennas. In an embodiment, the antenna unit 410 may have a first antenna 411 and a second antenna 413. On the other hand, the antenna unit 410 may have three or more antennas. Each of the first antenna 411 and the second antenna 413 may be implemented with a coil having a plurality of turns. The first antenna 411 and the second antenna 413 may be electrically connected to the RF power supply 420 to receive a RF power. The first antenna 411 and the second antenna 413 may be arranged in a position which is opposite to the substrate W. For example, the first antenna 411 and the second antenna 413 may be installed on the process chamber 100. The first antenna 411 and the second antenna 413 may have a ring shape. Here, a radius of the first antenna 411 may be smaller than that of the second antenna 413. The first antenna 411 may be located in a center area of the top surface of the process chamber 100. The second antenna 413 may be located in a boundary area of the top surface of the process chamber 100.

In an embodiment, the first antenna 411 and the second antenna 413 may be arranged on a sidewall of the process chamber 100. In one embodiment, one of the first antenna 411 and the second antenna 413 may be arranged on the process chamber 100 and the other may be arranged on the sidewall of the process chamber 100. A position of an antenna may not be limited as long as a plurality of antennas generate plasma in the process chamber 100.

The first antenna 411 and the second antenna 413 may receive a RF power from the RF power supply 420 to induce a time-variable electromagnetic field in the process chamber 100, thereby making it possible for a process gas provided to the process chamber 100 to be excited into a plasma state.

The power divider 430 may distribute a power from the RF power 420 into antennas. In an embodiment, when impedance of one of a plurality of antennas increases but impedance of the other thereof decreases, the power divider 430 may easily control the amount of power, which is provided to each antenna, and a ratio thereof.

FIG. 3 is a circuit diagram illustrating a plasma generating unit 400 shown in FIG. 2. A plasma generating unit 400 may further include an impedance matcher 440. The impedance matcher 440 may be connected to an output terminal of a RF power supply 420 to match input impedance of a load side with an output impedance of a power side. In an embodiment, the impedance matcher 440 may be connected between the RF power supply 420 and an antenna unit 410 via a supply line 425. The impedance matcher 440 may include a first sensor 441, a second sensor 442, an inductor 443, a first variable capacitor 444, and a second variable capacitor 445. The first sensor 441 may be connected to an input terminal. The first sensor 441 may measure input impedance Zᵢₙ. The second sensor 442 may be connected to an output terminal. The second sensor 442 may measure output impedance Zₚₗ. The inductor 443 may be connected between the first sensor 441 and the second sensor 442 via the supply line 425. The first variable capacitor 444 may be serially connected to the inductor 443. As shown in FIG. 2, the first variable capacitor 444 may be connected between the inductor 443 and the second sensor 442. The second variable capacitor 445 may be connected to the first variable capacitor 444 in parallel. The second variable capacitor 445 may be connected between a division point P and a ground via the division line 426. The division line 426 may be divided from the division point P on the supply line 425. An end of the division line 426 may be grounded. The division line 426 may be located between the inductor 443 and the first sensor 441.

The controller 450 may transmit a control signal to the impedance matcher 440. The controller 450 may control matching impedance Zₘ of the impedance matcher 440. In an embodiment, the controller 450 may control value C1 of the first variable capacitor 444 and value C2 of the second variable capacitor 445.

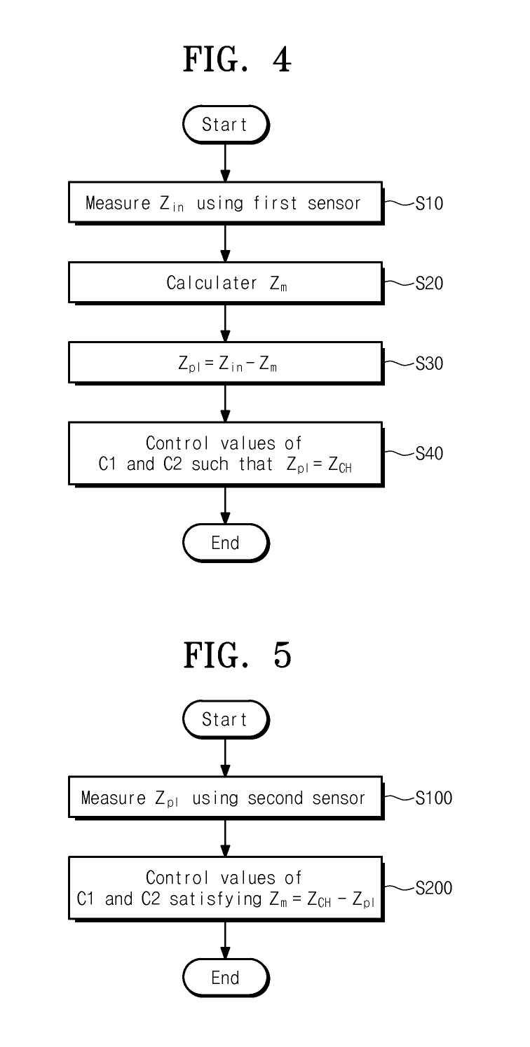

FIG. 4 is a flow chart illustrating a general matching control method according to a related art. In a conventional substrate treating apparatus, a sensor for measuring a resistance value may be connected to an input terminal of an impedance matcher. The substrate treating apparatus may measure input impedance Zᵢₙ using a first sensor 441 connected to the input terminal (S10). The substrate treating apparatus may calculate matching impedance Zₘ (S20), and then, may calculate output impedance Zₚₗ (S30). The substrate treating apparatus may set value C1 of the first variable capacitor and value C2 of the second variable capacitor such that the calculated output impedance Zₚₗ corresponds to characteristic impedance Z_{CH} (S40). Here, because impedances of a parasitic capacitor and an inductor in the impedance matcher are not taken into account, the substrate treating apparatus may iteratively search for a final matching value, thereby increasing a matching time and causing a process failure. Furthermore, the matching time of about 3 seconds may be needed when a pressure in a process chamber is changed.

FIG. 5 is a flow chart illustrating a matching control method according to an embodiment of the inventive concept. A substrate treating apparatus 10 may measure output impedance Zₚₗ using a second sensor 442 (S100). After the output impedance Zₚₗ is measured, a controller 450 may draw an impedance map satisfying a condition of matching impedance Zₘ. Here, the matching impedance Zₘ may be a difference between characteristic impedance Z_{CH} and the output impedance Zₚₗ. In an embodiment, the characteristic impedance Z_{CH} may be 50Ω. Therefore, the substrate treating apparatus 10 may control value C1 of the first variable capacitor 444 and value C2 of the second variable capacitor 445, which satisfy the phase and magnitude of impedance, within a short time (S200). Furthermore, when a pressure in a process chamber 100 is changed, the matching time about 0.7 seconds may be needed.

A baffle unit 500 may be located between an inner sidewall of a housing 110 and a substrate support unit 200. The baffle unit 500 may include a baffle in which penetration holes are formed. The baffle may have a ring shape. A process gas provided in a housing 100 may be exhausted to an exhaust hole 102 through the penetration holes in a baffle. A flow of a process gas may be controlled according to a shape of a baffle and a penetration holes.

Aforementioned variable elements may receive a control signal from a controller 450 to change values of the variable elements. The controller 450 may control a plasma characteristic so as to be suitable for a corresponding process by adjusting the values of the variable elements based on a process using plasma.

While the inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. An apparatus for treating a substrate, comprising:
a process chamber;
a support unit supporting the substrate in the process chamber;
a gas supply unit supplying a process gas in the process chamber; and
a plasma generating unit generating plasma from the process gas supplied in the process chamber,
wherein the plasma generating unit comprises:
a high frequency power supply;
an antenna unit connected to the high frequency power via a supply line; and
an impedance matcher connected between the high frequency power supply and the antenna unit via the supply line and configured to match impedance, and
wherein the impedance matcher comprises:
a first sensor connected to an input terminal and configured to measure input impedance; and
a second sensor connected to an output terminal and configured to measure output impedance.

2. The apparatus of claim 1, wherein the impedance matcher further comprises:
an inductor connected between the first sensor and the second sensor via the supply line;
a first variable capacitor connected between the inductor and the second sensor; and
a second variable capacitor connected to the first variable capacitor in parallel.

3. The apparatus of claim 2, wherein the plasma generating unit further comprises a controller configured to transmit a control signal to the impedance matcher, and
wherein the controller controls values of the first valuable capacitor and the second valuable capacitor after measuring the output impedance using the second sensor.

4. The apparatus of claim 3, wherein the second variable capacitor is connected between a division point of the supply line and a ground.

5. The apparatus of claim 4, wherein the division point is located between the first sensor and the inductor.

6. The apparatus of claim 5, wherein the antenna unit comprises:
a first antenna connected to the high frequency power supply through a supply line; and
a second antenna connected to the first antenna in parallel.

7. The apparatus of claim 6, wherein each of the first antenna and the second antenna has a ring shape, and
wherein a radius of the first antenna is smaller than that of the second antenna.

8. A plasma generating unit, comprising:
a high frequency power supply;
an antenna unit connected to the high frequency power via a supply line; and
an impedance matcher connected between the high frequency power supply and the antenna unit via the supply line and configured to match impedance, and
wherein the impedance matcher comprises:
a first sensor connected to an input terminal and configured to measure input impedance; and
a second sensor connected to an output terminal and configured to measure output impedance.

9. The plasma generating unit of claim 8, wherein the impedance matcher further comprises:
an inductor connected between the first sensor and the second sensor via the supply line;
a first variable capacitor connected between the inductor and the second sensor; and
a second variable capacitor connected to the first variable capacitor in parallel.

10. The plasma generating unit of claim 9, wherein the plasma generating unit further comprises:
a controller configured to transmit a control signal to the impedance matcher, and
wherein the controller controls values of the first valuable capacitor and the second valuable capacitor after measuring the output impedance using the second sensor.

11. The plasma generating unit of claim 10, wherein the second variable capacitor is connected between a division point of the supply line and a ground.

12. The plasma generating unit of claim 11, wherein the division point is located between the first sensor and the inductor.
